(19) United States
(12) Patent Application Publication
(10) Pub. No.: US 2004/0022026 A1
(43) Pub. Date: Feb. 5, 2004

(54) Stacked electronic device modules with heat pipes

(76) Inventors: Christian L. Belady, McKinney, TX (US); Stuart C. Haden, Lucas, TX (US)

Correspondence Address: HEWLETT-PACKARD COMPANY, Intellectual Property Administration, P.O. Box 272400, Fort Collins, CO, 80527-2400, US

(21) Appl. No.: 10/209,853

(22) Filed: Jul. 31, 2002

(51) Int. Cl. H05K 7/20

(52) U.S. Cl. 361/700; 62/259.2; 174/15.2

(57) ABSTRACT

A stacked electronic device module is constructed incorporating heat pipes within the module, enabling efficient cooling of the electronic devices within the module. The heat pipes may extend outside of the stacked electronic device modules for more efficient operation. Heat pipes may be placed selectively between some layers of the module or placed between each layer of the module.

### FIELD OF THE INVENTION

The present invention relates generally to the field of stacked electronic device modules, and more specifically to the field of thermal cooling of stacked electronic device modules.

### BACKGROUND OF THE INVENTION

Modern electronics have benefited from the ability to fabricate devices on a smaller and smaller scale. This shrinking is occurring not only with integrated circuits themselves, but also with systems incorporating multiple integrated circuits. One example of this decrease in size is the current capability of closely stacking modules containing one or more integrated circuit. Unfortunately, this stacking, while dramatically increasing the density of the resulting module, dramatically reduces or eliminates entirely the dissipation of heat from the incorporated integrated circuits to the surrounding atmosphere.

This heat may build up within the stacked electronic device module to the point that circuits within the module fail to operate correctly due to their internal temperature rising above their design limits. Also, it is well known that most integrated circuit devices switch slower at high temperature than they do at lower temperatures, resulting in a decrease in performance of the device.

As the power density of electronic device modules increases, heat transfer from the heat generating devices to the surrounding environment becomes more and more critical to the proper operation of the devices. Many current electronic devices incorporate heat sink fins to dissipate heat to the surrounding air moving over the fins. However, as alluded to above, stacked electronic device modules often are not configured to allow airflow over all of the integrated circuits, or other electronic devices, within the module.

### SUMMARY OF THE INVENTION

A stacked electronic device module is constructed incorporating heat pipes within the module, enabling efficient cooling of the electronic devices within the module. The heat pipes may extend outside of the stacked electronic device modules for more efficient operation. Heat pipes may be placed selectively between some layers of the module or placed between each layer of the module.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is an illustration of three example electronic device modules.

FIG. 2 shows an example stack up of seven example electronic device modules.

FIG. 3 is a cross-section diagram of an example embodiment of stacked electronic device modules.

FIG. 4 is a cross-section diagram of a portion of the example embodiment of a stacked electronic device module from FIG. 3.

FIG. 5 is a cross-section diagram of an example embodiment of stacked electronic device modules including heat pipes according to an example embodiment of the present invention.

FIG. 6 is a cross-section diagram of a portion of the example embodiment of stacked electronic device modules including heat pipes according to an example embodiment of the present invention from FIG. 5.

FIG. 7 is a cross-section diagram of an example embodiment of stacked electronic device modules including heat pipes according to an example embodiment of the present invention including heat pipes that extend beyond the body of the stacked electronic device modules.

FIG. 8 is a cross-section diagram of an example embodiment of stacked electronic device modules including heat pipes according to an example embodiment of the present invention including heat pipes that extend beyond the body of the stacked electronic device modules and are thermally coupled to an external heat sink.

FIG. 9 is a flowchart of an example method for the fabrication of stacked electronic device modules including heat pipes according to the present invention.

### DETAILED DESCRIPTION

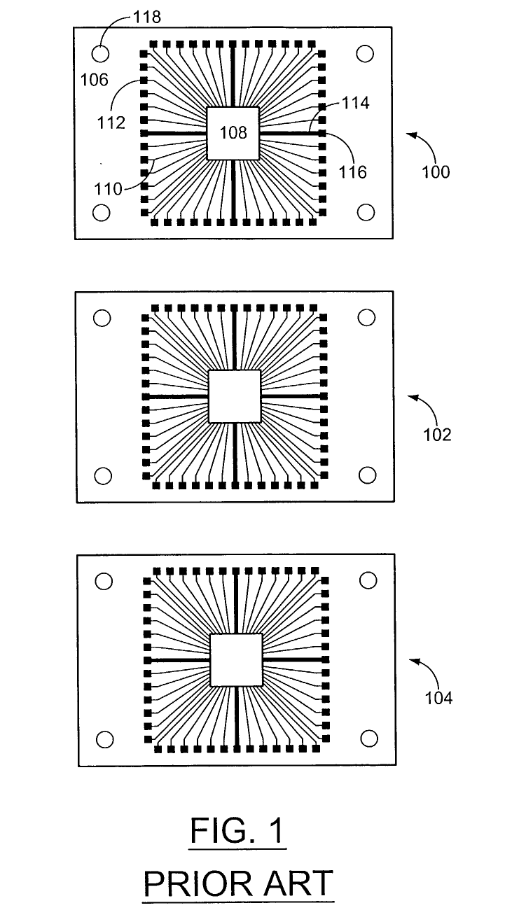

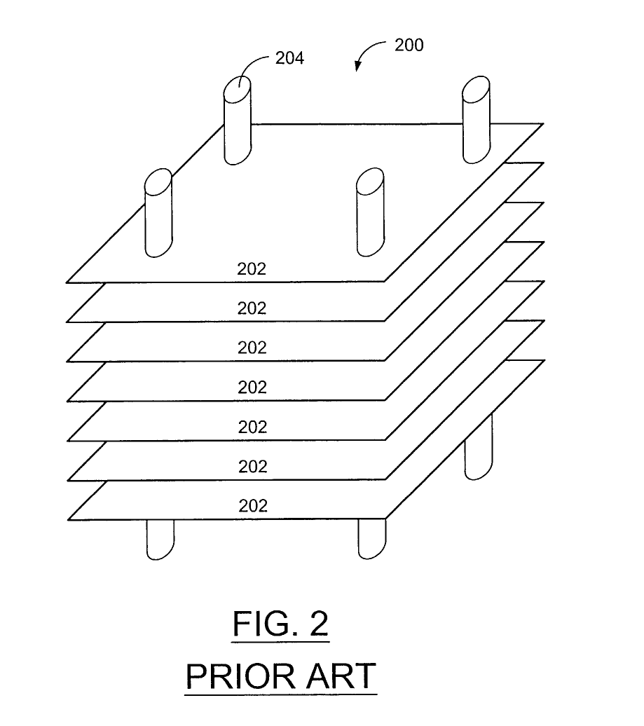

FIG. 1 is an illustration of three example electronic device modules. The first electronic device module 100, second electronic device module 102, and third electronic device module 104, shown in FIG. 1 are all identical in this example of a plurality of electronic device modules. Each of the electronic device modules includes an electronic device 108, such as an integrated circuit, attached to the substrate 106 of the module. Also shown are signal conductors 110 connecting the electronic device 108 to signal contacts 112. Further, wide power conductors 114 connect the electronic device 108 to power contacts 116. These signal contacts 112 and power contacts 116 may be electrically connected to signal and power conductors within the substrate 106 of the module or may connect to signal and power conductors on other modules after the three modules 100, 102, and 104 are incorporated into a single stacked electronic device module similar to that shown in FIG. 2. This stacking of individual modules is facilitated by the use of alignment holes 118 in this example, however, many other methods of alignment of the individual modules may be used, such as external assembly jigs, pins and sockets, or clips.

FIG. 2 shows an example stack up of seven example electronic device modules. In this example stack up 200, seven electronic device modules 202 are aligned through the use of pins 204 through individual alignment holes of the individual modules similar to those shown in FIG. 1.

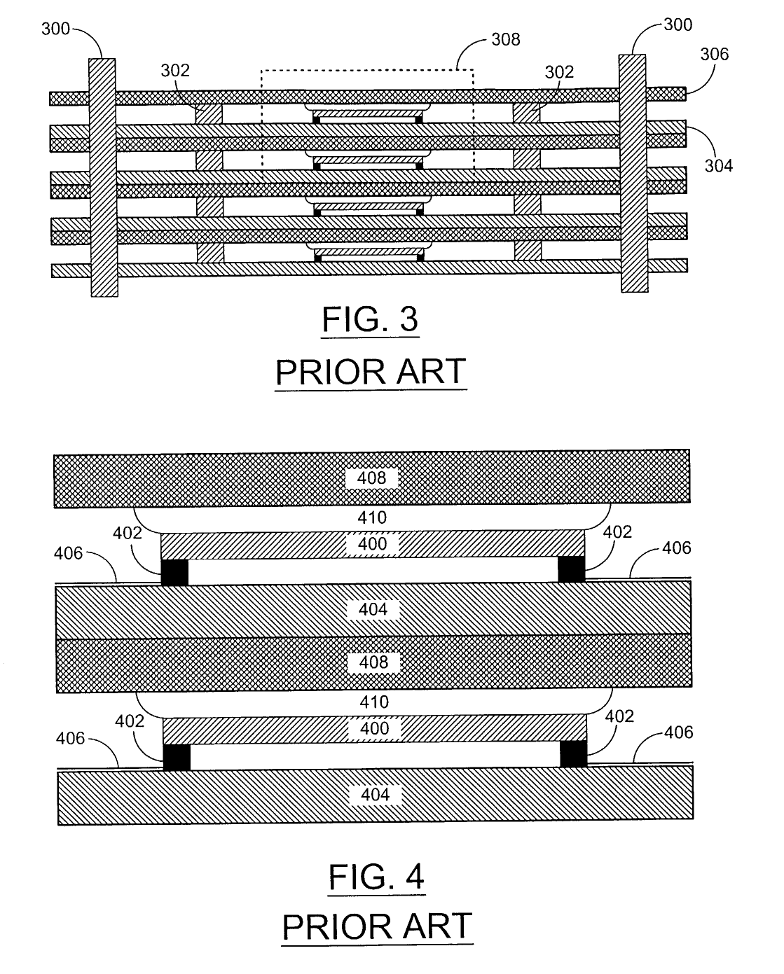

FIG. 3 is a cross-section diagram of an example embodiment of stacked electronic device modules. Four electronic device modules 304 are shown stacked with four heat spreaders 306 in this example embodiment of stacked electronic device modules. Similar to the example in FIG. 2, pins 300 are used to align the modules 304, and spacers 302 are used to keep the modules coplanar. The area enclosed by the dashed line of reference number 308 is enlarged and shown in FIG. 4.

FIG. 4 is a cross-section diagram of a portion of the example embodiment of a stacked electronic device module from FIG. 3. This cross-section view, shows the stack up of two electronic device modules. Each module includes a substrate 404, and an electronic device 400 electrically connected to signal conductors 406 through pads 402. The modules are stacked with heat spreaders 408 connected to the electronic devices 400 with a thermally conductive paste 410 or other similarly thermally conductive material.

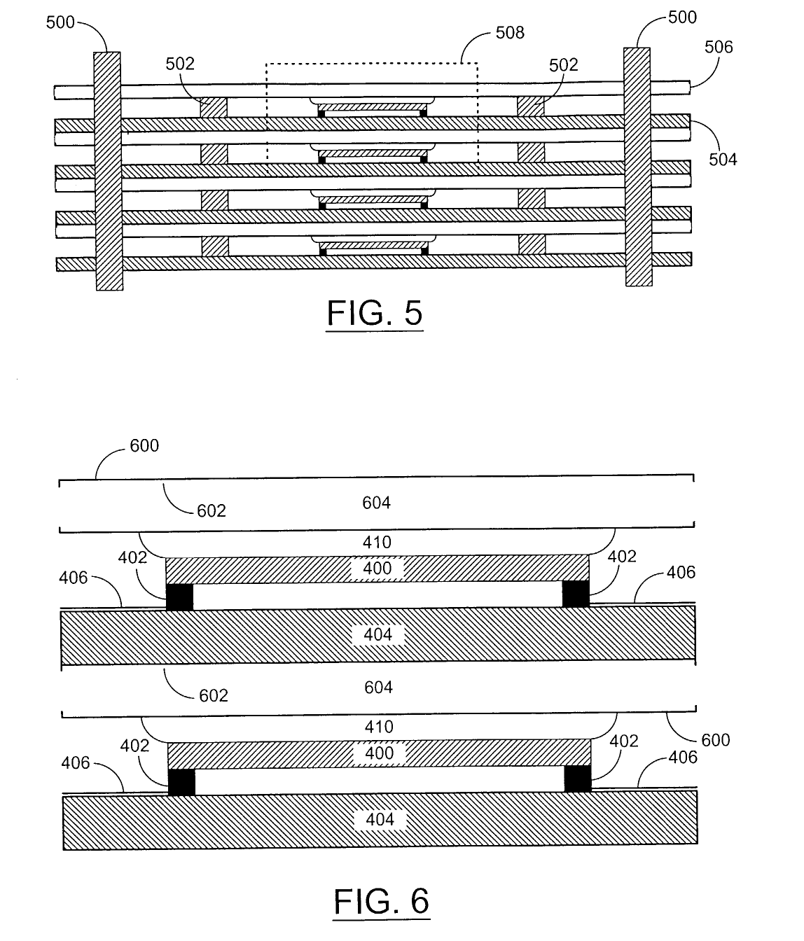

FIG. 5 is a cross-section diagram of an example embodiment of stacked electronic device modules including heat pipes according to an example embodiment of the present invention. Four electronic device modules 504 are shown stacked with four heat pipes 506 in this example embodiment of stacked electronic device modules. Pins 500 are used to align the modules 504, and spacers 502 are used to keep the modules coplanar. The area enclosed by the dashed line of reference number 508 is enlarged and shown in FIG. 6.

FIG. 6 is a cross-section diagram of a portion of the example embodiment of stacked electronic device modules including heat pipes according to an example embodiment of the present invention from FIG. 5. This cross-section view, shows the stack up of two electronic device modules. Each module includes a substrate 404, and an electronic device 400 electrically connected to signal conductors 406 through pads 402. The modules are stacked with heat pipes 600 connected to the electronic devices 400 with a thermally conductive paste 410 or other similarly thermally conductive material. The heat pipe 600 comprises a vapor 604 surrounded by a wick 602 within the vessel of the heat pipe 600. Where the heat pipe 600 is thermally connected to the electronic device 400 through thermal paste 410, the liquid within the wick 602 evaporates to form a vapor 604. This heated vapor travels within the heat pipe 600 to the cooler area outside of the stacked electronic device module, where the vapor 604 condenses on the wick 602 into a liquid that then flows back through the wick 602 to the warmer area of the heat pipe 600, where the process continues.

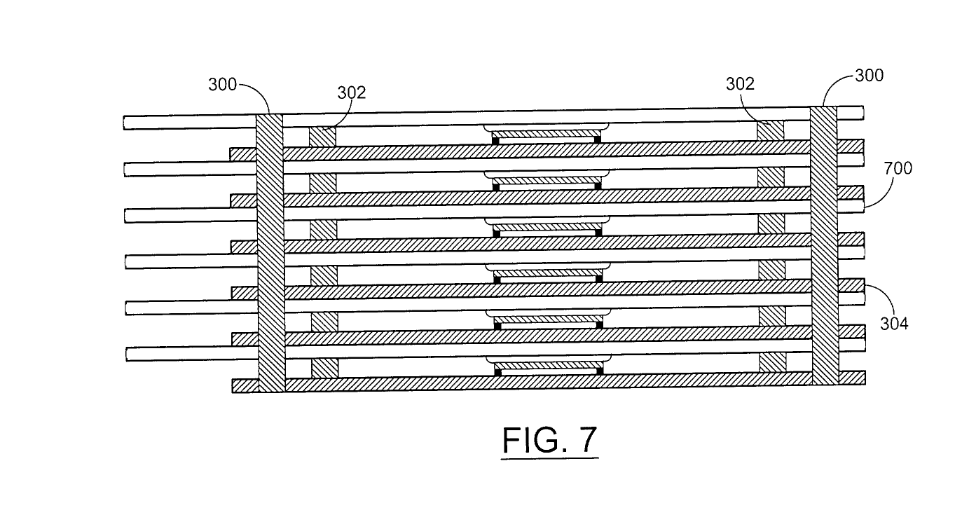

FIG. 7 is a cross-section diagram of an example embodiment of stacked electronic device modules including heat pipes 700 according to an example embodiment of the present invention including heat pipes 700 that extend beyond the body of the stacked electronic device modules. In some embodiments of the present invention it may be useful to extend the heat pipes 700 beyond the body of the stacked electronic device modules allowing air to flow over the surfaces of the heat pipes 700 external to the body of the stacked electronic device modules resulting in greater efficiency of cooling the module.

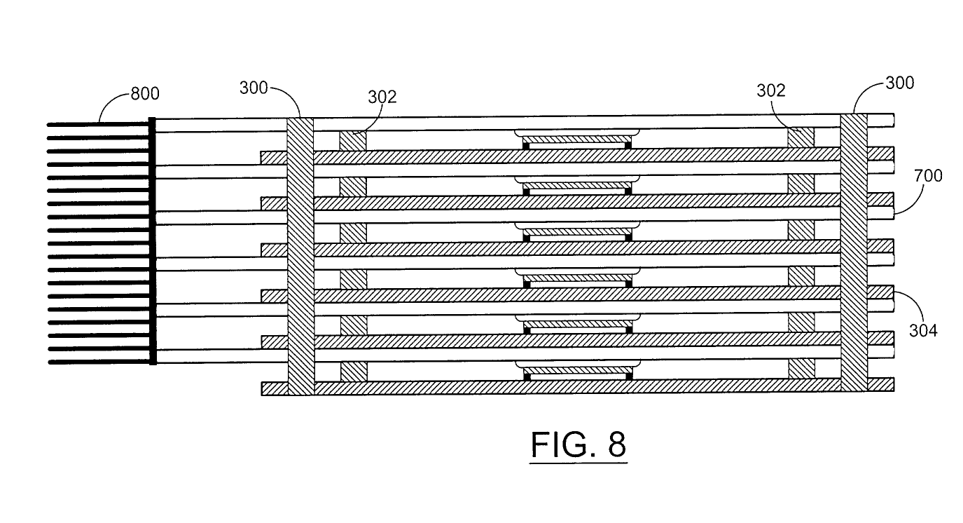

FIG. 8 is a cross-section diagram of an example embodiment of stacked electronic device modules including heat pipes according to an example embodiment of the present invention including heat pipes that extend beyond the body of the stacked electronic device modules and are thermally coupled to an external heat sink. In other embodiments of the present invention further efficiency may be obtained by thermally coupling an external heat sink 800 to the heat pipes 700. In this example embodiment, an external heat sink 800 is thermally and mechanically coupled to heat pipes 700 similar to those shown in FIG. 7 that extend beyond the body of the stacked electronic device module. However, other embodiments of the present invention may attach an external heat sink 800 to the ends of heat pipes 700 that do not extend beyond the body of the module.

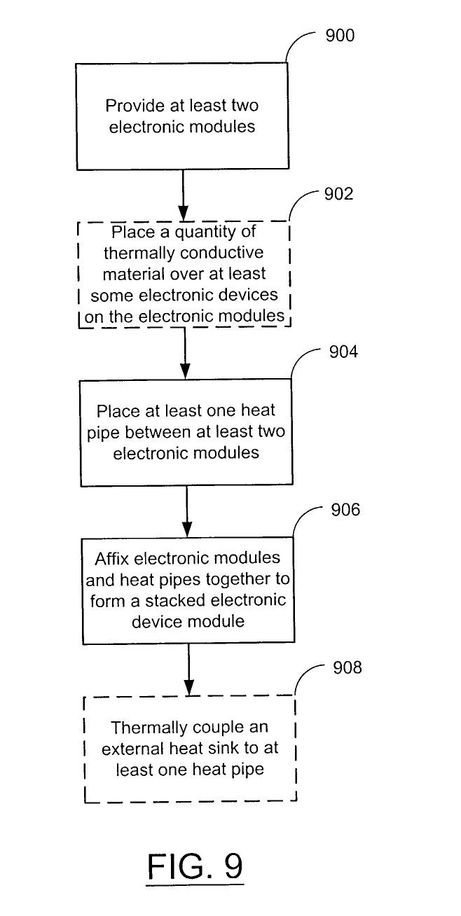

FIG. 9 is a flowchart of an example method for the fabrication of stacked electronic device modules including heat pipes according to the present invention. In order to construct a stacked electronic device module including heat pipes according to the present invention, at least two electronic modules must be provided in a step 900. In an optional step 902, thermally conductive material such as a thermal paste is placed over at least some of the electronic devices included on the electronic modules. In a step 904, at least one heat pipe is placed between the electronic modules. In a step 906, the heat pipes and electronic modules are affixed together to form a stacked electronic device module. This step may be accomplished by mechanical means such as nuts and bolts, pins, glue, or encapsulation. Many such methods for affixing the heat pipes and electronic modules together may be used within the scope of the present invention. In an optional step 908, an external heat sink may be thermally coupled to at least one of the heat pipes to improve cooling efficiency.

In some example embodiments of the present inventions, stacked modules (such as the memory stacks and memory modules produced by DPAC Technologies, 1721 Lincoln Way, Garden Grove, Calif., 92841, www.dpactech.com, or the memory modules and processor cores produced by 3D Plus USA, Inc., 1947 Ave. K, Suite D, Plano, Tex. 75074) may be built with heat pipes interspersed between the individual layers of the stack or module. For modules including electrical connections on the outside of the module, some implementations of the present invention may eliminate some or all of the electrical connections on one or more sides of the module to allow the heat pipes access to the external atmosphere for increased cooling performance.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A stacked electronic device module comprising:
at least two electronic device modules; and
at least one heat pipe thermally coupled with at least one of said electronic device modules, wherein said heat pipe is physically located between at least two of said electronic device modules configured such that said heat pipe transfers thermal energy out of said stacked electronic device module.

2. A stacked electronic device module as claimed in claim 1, wherein:
said at least two electronic device modules each include at least one integrated circuit.

3. A stacked electronic device module as claimed in claim 2, wherein:
said at least one heat pipe is thermally coupled with said at least one integrated circuit.

4. A stacked electronic device module as claimed in claim 1, further comprising:
an external heat sink thermally coupled to at least one of said at least one heat pipe.

5. A stacked electronic device module as claimed in claim 1, wherein:
said at least one heat pipe extends outside of said stacked electronic device module.

6. A stacked electronic device module as claimed in claim 5, further comprising:
an external heat sink thermally coupled to at least one of said at least one heat pipe.

7. A stacked electronic device module as claimed in claim 1, wherein:
at least two of said at least two electronic device modules are electrically connected.

8. A method for constructing a stacked electronic device module comprising the steps of:
(a) providing at least two electronic modules;
(b) placing at least one heat pipe between the at least two electronic modules; and
(c) affixing the at least two electronic modules and at least one heat pipe together in a configuration forming a stacked electronic device module.

9. A method for constructing a stacked electronic device module as claimed in claim 8, further comprising the step of:
(d) placing a quantity of thermally conductive material over at least some electronic devices on the at least two electronic modules.

10. A method for constructing a stacked electronic device module as claimed in claim 8, further comprising the step of:
(d) thermally coupling an external heat sink to at least one of the heat pipes.

11. A method for constructing a stacked electronic device module as claimed in claim 8, further comprising the step of:
(d) electrically connecting at least two of the at least two electronic device modules.

12. A stacked electronic device module comprising:
at least two electronic device modules;
means for physically connecting said at least two electronic device modules into a stack; and
heat pipe means for removing heat from between said at least two electronic device modules.

13. A stacked electronic device module as claimed in claim 12, further comprising:
means for electrically connecting at least two of said at least two electronic device modules.
